(19) United States
(12) Patent Application Publication
(10) Pub. No.: US 2006/0237626 A1
(43) Pub. Date: Oct. 26, 2006

(54) DIGITAL CAMERA

(75) Inventors: Masayuki Sakai, Asaka (JP); Kazuhisa Horikiri, Asaka (JP); Seimei Ushiro, Asaka (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 11/379,248

(22) Filed: Apr. 19, 2006

(30) Foreign Application Priority Data
Apr. 26, 2005 (JP) 2005-127859

(51) Int. Cl. H01L 27/00

(52) U.S. Cl. 250/208.1

(57) ABSTRACT

A digital camera has a display screen that improves an external design of the digital camera. The display screen is disposed on a front surface of the digital camera, which surface faces a subject when an image-taking optical system is directed to the subject. The display screen is capable of displaying an image such as a design image or a clock image. The digital camera is also capable of automatically displaying a through image when detecting a subject distance being shorter than a predetermined distance, i.e. a self-portrait is going to be taken. The digital camera is also capable of displaying an image based on personal image data so that a user can enjoy its external design.

### BACKGROUND OF THE INVENTION

1. Field of the Invention

The present invention relates to a digital camera that includes an image-taking optical system and an imaging device and causes the imaging device to generate image signals representing a subject image by forming the subject image on the imaging device using the image-taking optical system.

2. Description of the Related Art

Many of portable devices such as digital cameras are configured to have at least one display screen and to be capable of displaying various kinds of information on the display screen. Japanese Patent Application Publication No. 2003-188959 discloses one of such devices, which is a folding portable telephone with camera. The portable telephone in this publication has two display screens: one for displaying incoming-call numbers and the other serving as a main panel. Also, for example, Japanese Patent Application Publication No. 2004-297251 discloses a similar portable telephone with camera, which has a touch panel disposed on each of two display screens on the front and back thereof and is configured to perform shooting when a user touches both panels at the same time, in order to improve the positional stability of the telephone.

In either case, one display screen is disposed in a position where it can be seen from outside to serve as a part of the outer cover.

By the way, some of portable device users place importance on not only the shape but also the exterior design of the device because nowadays the design of the device often draws people's attention, for example, when a user holds the device while walking. The number of such design-conscious users is increasing. In view of these circumstances, it is conceivable to employ techniques disclosed in Japanese Patent Application Publications No. 2003-43959 and No. 2004-133131 which can provide an outer cover with a design attractive to users by incorporating a luminescent sheet into a display screen of the outer cover to make it brilliant. However, it is desired to conceive more appealing designs. Also, while a display screen is employed in view of design in this manner, it is desirable to maintain the conventional function.

### SUMMARY OF THE INVENTION

The present invention has been made in view of the above circumstances, and provides a digital camera having an exterior design improved further than conventional devices by using a display screen.

A digital camera according to the invention has an image-taking optical system and an imaging device and generates image signals by forming a subject image on the imaging device with the image-taking optical system, including:

a display screen which is disposed on a front surface of the digital camera and displays an image, the front surface facing a subject when the image-taking optical system is directed to the subject; and

a display control section which displays an image on the display screen.

In this digital camera, the display screen is disposed on the front surface of the digital camera facing a subject when the image-taking optical system is directed to the subject, and the display control section causes the display screen to display various images by controlling it.

With this configuration, under the control of the display control section, one of various images such as a subject image, a design image serving as a part of an outer cover, and the like can be freely selected and displayed on the display screen even when the digital camera is carried and even during shooting.

In this way, it is possible to realize a digital camera having an external design further improved than before.

Further, in the digital camera according to the invention, the display screen may be disposed on the left of the image-taking optical system on the front surface when viewed from the subject. Furthermore, the display screen may be adapted to continuously display an image even after a power supply is stopped.

These additional features make it possible to dispose the screen display on a position that makes it inconspicuous during shooting while making it relatively conspicuous when the digital camera is carried. In addition, these features enable the display screen to display various design images while the digital camera is carried, which serve as a part of the exterior design, thereby making the digital camera further attractive.

Still further, in the digital camera according to the invention, the display control section may cause the display screen to continuously display an image for a predetermined time even after power is turned off.

This additional feature allows a user to check the last taken image within a predetermined time even after the power is unintentionally turned off. In addition, this feature allows a user to enjoy the change of design because another design image is displayed after a lapse of predetermined time by replacing the image displayed immediately after the power is turned off.

Additionally, the digital camera according to the invention may further include a sensor which detects a physical movement of the digital camera caused by an external force,

wherein the display control section may cause the display screen to display an image in response to a physical movement being detected by the sensor even when power is turned off.

This additional feature makes the digital camera convenient by allowing a user to skip operation for turning on of the power, because the power is automatically turned on to activate the digital camera in response to a movement being detected by the sensor when, for example, the digital camera is lifted.

Also, the digital camera according to the invention may further include a distance measuring section which measures a subject distance before shooting,

wherein the display control section causes the display screen to display an image captured by the image-taking optical system when a distance shorter than a predetermined distance is measured by the distance measuring section.

This additional feature enables the digital camera to determine that shooting of a self-portrait is likely to take place and to display an image captured by the image-taking optical system on the display screen, when a distance shorter than a predetermined distance is measured by the distance measuring section.

In this feature, a self-portrait is displayed on the display screen that serves as a finder.

As described above, it is possible to realize a digital camera having an exterior design improved further than before according to the invention.

### BRIEF DESCRIPTION OF THE DRAWINGS

FIG. 1 is an external view of a digital camera according to an embodiment of the present invention;

FIG. 2 is a diagram showing examples of an image displayed on a display screen disposed on the front of the digital camera according to the embodiment based on image data sent from an IR (InfraRed) transmitter;

FIG. 3 is a diagram showing an internal configuration of the digital camera shown in FIG. 1;

FIG. 4 is a diagram showing the structure of an electronic display sheet employing an electronic paper;

FIG. 5 is a conceptual diagram showing the structure of a cell of the electronic paper;

FIG. 6 is a diagram showing another examples of an image to be displayed based on image data transmitted from the IR transmitter;

FIG. 7 is a diagram showing an image displayed on the display screen when a user takes a self-portrait;

FIG. 8 is a diagram showing a timer value that indicates timing for shooting a self-portrait;

FIG. 9 is a diagram showing an example in which a self-portrait as a user-customized image is displayed;

FIG. 10 is a diagram showing an example in which a clock is displayed;

FIG. 11 is a diagram showing another example of the display screen serving as a part of an exterior design;

FIG. 12 is a diagram showing another example of the display screen serving as a part of an exterior design; and

FIG. 13 is a diagram showing another example of the display screen serving as a part of an exterior design.

### DETAILED DESCRIPTION OF THE INVENTION

An embodiment of the present invention will be described with reference to the drawings.

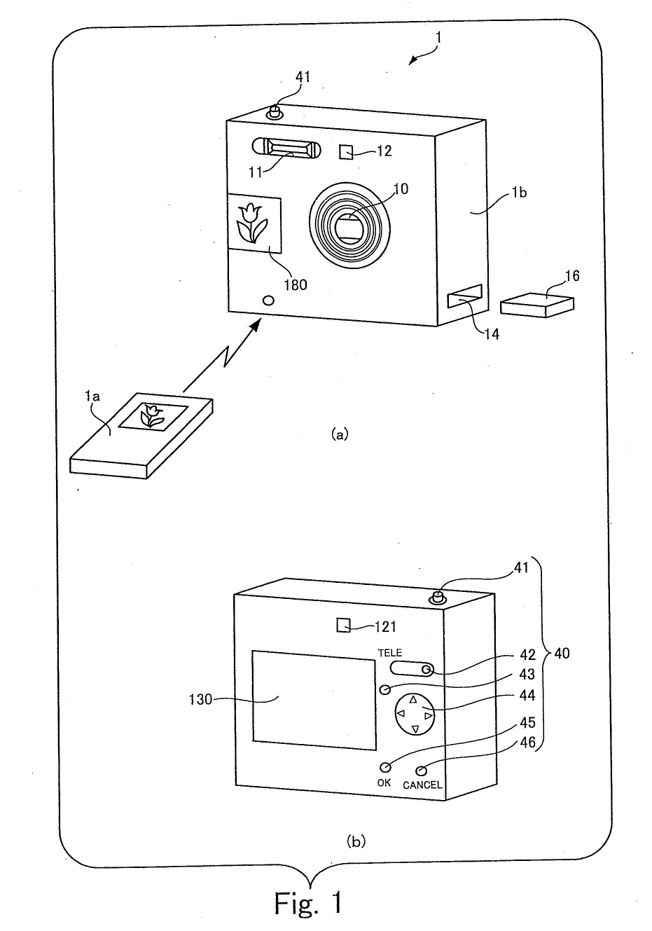

FIG. 1 is an external view of a digital camera 1 according to an embodiment of the present invention.

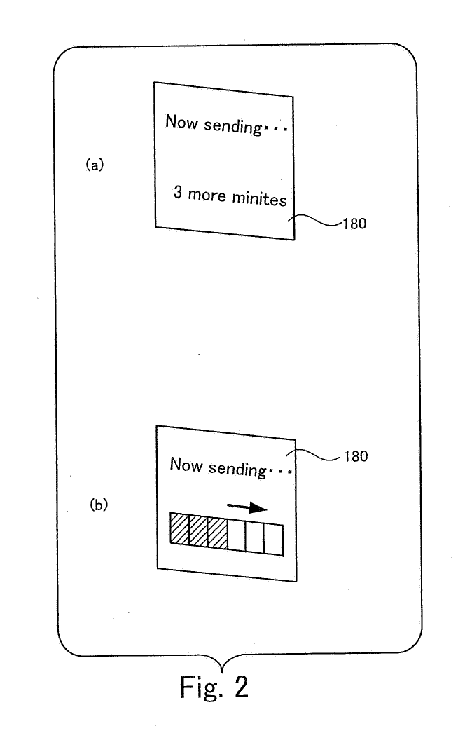

Part (a) and Part (b) of FIG. 1 are perspective views of the front and back of the digital camera 1, as viewed obliquely from above, respectively. FIG. 2 is a diagram showing examples of an image displayed on a display screen 180 of the digital camera 1 according to the embodiment based on image data sent from an InfraRed (IR) transmitter 1a which will be described later.

As shown in Part (a) of FIG. 1, the display screen 180 is disposed on the front surface of the digital camera 1, which surface faces a subject when an image-taking optical system of the digital camera 1 is directed to the subject. The display screen 180 is disposed on the left of a lens barrel 10 on the front of a camera body 1b. The image-taking optical system is built in the lens barrel 10. In this embodiment, the display screen 180 contains a display sheet made of an electronic paper and is configured to keep displaying the latest image even after the power is turned off, which is the image displayed immediately before the turning off of the power. In addition, the display screen 180 is configured to display an image based on image data sent from an external remote controller that is the IR transmitter 1a in this embodiment. As shown in FIG. 2, during data transmission from the IR transmitter 1a, the display screen 180 may display a massage: “Now sending . . . 3 more seconds.” as shown in Part (a) or a bar graph indicating the sending status as shown in Part (b).

Formed above the lens barrel 10 are a flash window 11 and a finder objective window 12. In addition, a release button 41 is disposed on the top face of the camera body 1b and a card slot 14 into which a memory card 16 is inserted from outside is formed on a flank of the camera body 1b.

As shown in Part (b) of FIG. 1, a display screen 130 and an operation section 40 on the right of the display screen 130 are disposed on the back of the camera body 1b. The operation section 40 includes operation members such as a zoom switch 42, a power switch 43, a cross key 44, an OK (MENU/OK) button 45 and a cancel button 46. The operation members 42 through 46 and the release button 41 may be collectively referred to as the operation section 40.

Above the display screen 130, there is formed a finder eyepiece window 121 used in a pair with the finder objective window 12. On the display screen 130, a through image (live view) is displayed upon press of the power switch 43, and a menu is displayed upon press of the MENU/OK button 45. Next, the internal configuration of the digital camera 1 shown in FIG. 1 will be described.

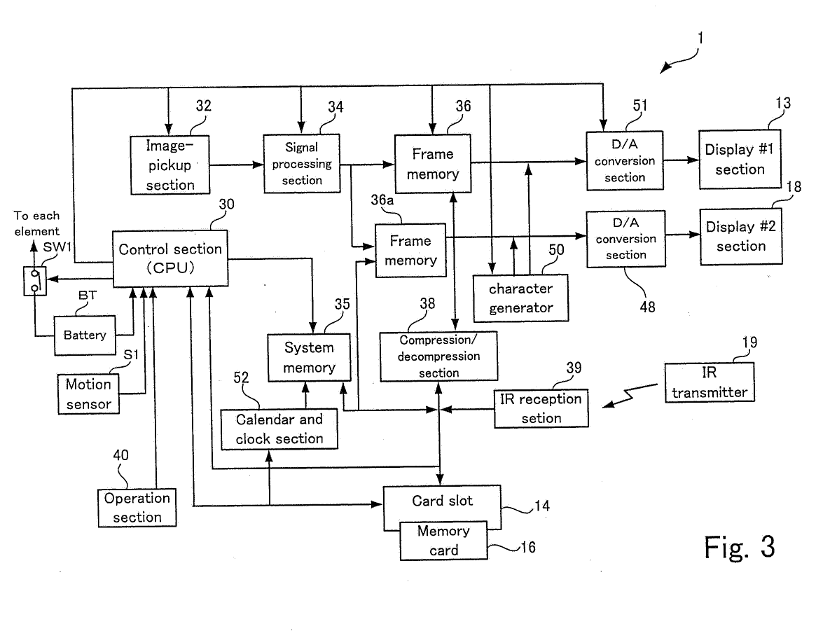

FIG. 3 is a diagram showing the internal configuration of the digital camera 1 shown in FIG. 1.

As shown in FIG. 3, a CPU 30 serving as a control section controls the whole operation of the digital camera 1. The CPU 30 controls the digital camera 1 according to a program stored in a system memory 35. The system memory 35 has a non-volatile ROM and a RAM and stores, in the RAM, data such as image data transmitted from the IR transmitter 1a and received by an IR reception section 39. The contents of the stored data are read from the RAM as required and transmitted to a frame memory 36a serving as a display buffer. If the work area is formed only by the RAM of the system memory 35, the stored data RAM would vanish when the power is turned off. Therefore, the work area is composed of the RAM and a non-volatile electrically erasable programmable ROM (EEPROM) and data that must remain even after the power is turned off is stored in the EEPROM side of the work area. The work area is also supplied with calendar and clock information from a calendar and clock section 52. When an image file is recorded in the memory card 16, the calendar and clock information is read out in real time to be recorded as shooting information in the header of the image file or to be transmitted to the frame memory 36a.

Upon reading information sent by the calendar and clock section 52 from the system memory 35, the CPU 30 converts the read information into character information, for example, “xx(month)/xx(date)/xxxx(year)” by controlling a character generator 50 and causes a display #2 section 18 to display the character information on the display screen 180. Also, upon reading image data representing a design image sent from the IR transmitter 1a out of the system memory 35, the CPU 30 transmits the read image data to the frame memory 36a and causes the display #2 section 18 to display the design image on the display screen 180.

In this way, the CPU 30 serving as a control section is capable of causing the display #2 section 18 to display various images such as a clock, a design image or the like as required. In the embodiment, the combination of the CPU 30 serving as a control section and the system memory 35 storing a program describing display-processing procedures executed by the CPU 30 corresponds to the “display control section” according to the invention.

Now, operation of the digital camera 1 shown in FIG. 1 will be briefly described with reference to FIG. 3

First, there will be described a circuitry configuration part relevant to display processing, which includes an image-pickup section 32 through a display #1 section 13. This part performs processing including displaying of a through image on the display screen 130 of the display #1 section 13, imposing of character information on a displayed through image, and the like.

The image-pickup section 32 includes an image-taking optical system built in the lens barrel 10 and an imaging device that generates image data representing a subject image formed thereon by means of the image-taking optical system. Image data generated here is subsequently output to a signal processing section 34 where the image data is converted into YC signals and sent there from to a frame memory 36 that stores the YC signals as image signals. The signal processing section 34 includes, in addition to a YC separator performing conversion into YC signals, an AF detector and an AE detector for detecting a focus and measuring field brightness.

The frame memory 36 serves as a display buffer used for displaying a through image and stores image data representing the image displayed on the display screen 130. The image data stored in the frame memory 36 is sent to a D/A conversion section 51 where the image data is converted into analog signals. The analog signals are then sent from the D/A conversion section 51 to the display #1 section 13 that causes the display screen 130 to display an image having a tone based on the received analog signals.

Although not shown in FIG. 3, there is a timing generator whose operation is controlled by the CPU 30 and which keeps supplying timing signals at predetermined intervals (intervals of 33 ms) to the imaging device. Therefore, image data representing an image formed on the imaging device, which changes with the time, is sequentially output to the image processing section 34. Then, based on the sequentially received image data, the image processing section 34 updates image data stored in the frame memory 36 serving as a display buffer. In other words, image data stored in the frame memory 36 is updated at intervals of 33 ms to change the image on the screen display 130 accordingly. This makes a user feel as if he/she is seeing a displayed image of a subject in real time to which the image-taking optical system camera is directed.

The digital camera 1 according to the embodiment is provided with the display screen 180 on the front as shown in FIG. 1 in addition to the display screen 130 on the back and therefore includes a display system for display on the display screen 180. The display #2 section 18 is capable of causing the display screen 180 to display images similarly to the display #1 section 13 and besides, design images based on image data stored in the system memory 35. To display a design image, image data representing the design image is read from the system memory 35 and sent to the frame memory 36a and further to a D/A conversion section 48 where the image data is subjected to D/A conversion. Finally, based on the image data after the D/A conversion, the design image is displayed on the display screen 180.

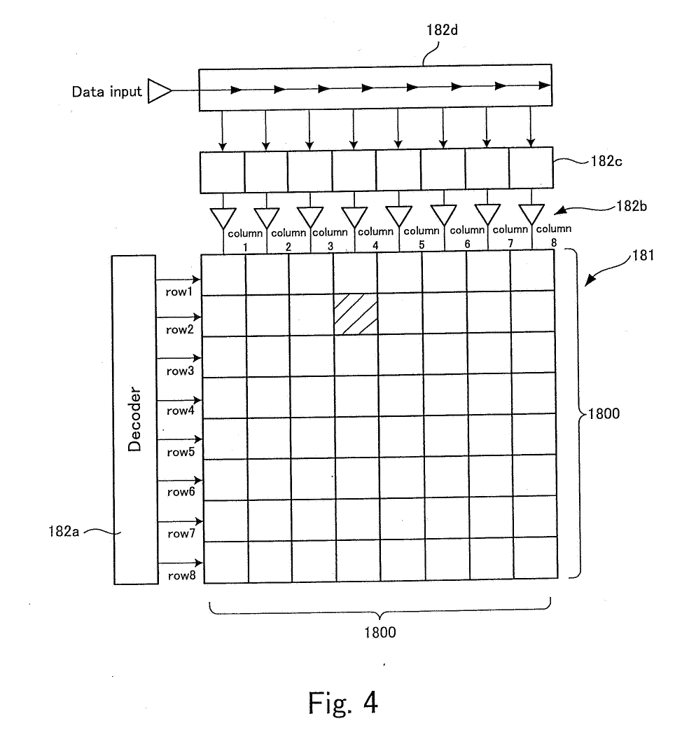

When such a design image is displayed on the display screen 180, it is desirable to keep the image displayed even after the power is turned off. Therefore, the digital camera 1 of the embodiment is configured to provide the display screen 180 of the display #2 section 18 with an electronic display sheet 181 (see FIG. 4) so that the display on the display screen 180 remains displayed even after the power is turned off.

Now, there will be briefly described the structure of the electronic display sheet 181 employing electronic paper.

FIG. 4 is a diagram showing the structure of the electronic display sheet 181 employing electronic paper. In FIG. 4, the D/A conversion section 48 shown in FIG. 3 is not illustrated because the electronic display sheet 181 shown in this figure is simply configured to control black and white display of arrayed cells, requiring no halftone display. If halftone control of this electronic display sheet is desired, a D/A conversion section may be disposed prior to a line driver 182b in parallel, and halftone data containing several bits, e.g. 8 bits, may be supplied to the D/A conversion section. In this case, a halftone can be adjusted by changing a composition ratio between white particles and black particles according to, for example, a voltage applied to each cell.

As shown in FIG. 4, the electronic display sheet 181 is composed of multiple cells 1800 arranged in matrix form. In the following description, a cell group in a vertical array is referred to as “column cell” and there are columns 1 through 8. In contrast, a cell group in a horizontal array is referred to as “row cell” and there are rows 1 through 8. A decoder 182a selects any one of the rows 1 through 8 whereas the line driver 182b selects any one of the columns 1 through 8. When any one of the cells 1800 is selected and a voltage is applied thereto, the color of the selected cell (e.g. a diagonally shaded cell) is changed. FIG. 4 shows a latch circuit 182c and a shift register 182d in addition to the decoder 182a and the line driver 182b.

When image data is supplied to the line driver 182b at predetermined intervals, various images are displayed on the electronic display sheet 181.

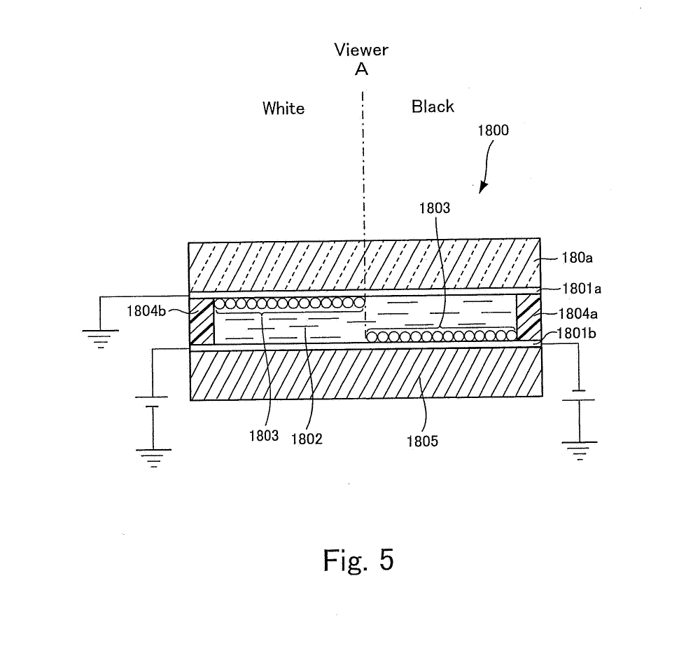

FIG. 5 is a conceptual diagram showing the structure of one cell 1800 as a representative example. The principle of the electronic display sheet 181 will be described with reference to FIG. 5.

As shown in FIG. 5, the cell 1800 is composed of a glass plate 180a, a pair of transparent electrodes 1801a and 1801b, a suspension 1802, multiple coloring particles 1803, a pair of spacers 1804a and 1804b, and a substrate 1805.

The multiple coloring particles 1803 are blended into the suspension 1802. The coloring particles 1803 and suspension 1802 are encapsulated by the pair of transparent electrodes 1801a and 1801b and the pair of spacers 1804a and 1804b. The transparent electrode 1801a is connected to the ground and the transparent electrode 1801b is configured to receive a voltage. When a positive or negative voltage is applied to the transparent electrode 1801b, the coloring particles 1803 are migrated and attracted to any one of the electrodes 1801a and 1801b. FIG. 5 illustrates both states.

The left part of FIG. 5 shows the state where a positive voltage is applied to the electrode 1801b disposed in the lower side in FIG. 5, causing the coloring particles 1803 to gather at the viewer A's side so that the viewer A can see white color. In contrast, the right part of FIG. 5 shows the state where a negative voltage is applied to the electrode 1801b disposed in the lower side in FIG. 5, enabling the viewer A to see the color of the suspension 1802, e.g. black color, instead of the color of the coloring particles 1803. After the migration, the coloring particles 1803 remain where they are even if the application of the voltage is stopped. The electronic display sheet 181 is composed of the multiple arrayed cells 1800 having such a structure. The use of such an electronic display sheet makes it possible to keep an image displayed even after the power is turned off.

Since an image remains displayed even after the power is turned off in this way, it is convenient to have the IR transmitter 1a capable of transmitting image data representing various designs.

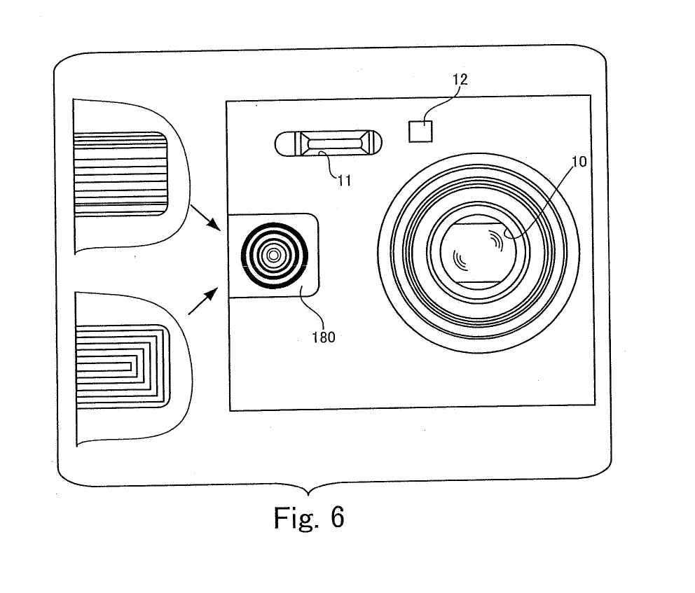

FIG. 6 is a diagram showing other examples of an image to be displayed based on image data transmitted from the IR transmitter 1a.

FIG. 6 shows two other design images each to replace the currently displayed image. The IR transmitter 1a is capable of transmitting various kinds of image data besides those images shown in FIG. 6. Accordingly, a user can freely change a part of the exterior design as desired.

There has been described, as an example, the use of the electronic paper in the display screen in which an image remains displayed even after the power is turned off. However, alternatively, a liquid crystal may be used in the display screen. In this case, an image may be continuously displayed on the display screen for a predetermined time even after the power is turned off by activating a timer in a CPU without shifting an analog switch to the off state.

Now, returning to FIG. 3, there will be described other functions of the digital camera 1 shown in FIG. 1 including shooting processing to be performed when the release button 41 is pressed while a through image is displayed on the display screen 130, which may not be particularly relevant to the feature of the invention.

Upon the press of the release button 41 in the operation section 40, the CPU 30 serving as a control section supplies the imaging device with an exposure-starting signal by controlling the timing generator. Subsequently, after a lapse of time according to a shutter speed corresponding to a detection result from the AE/AF detector of the signal processing section 34, the CPU 30 causes the timing generator to supply an exposure-ending signal.

Upon receipt of image signals which are generated by the imaging device in synchronization with the exposure-ending signal, the signal processing section 34 converts the received signals into YC signals which are then sent to and stored in the frame memory 36 as image data. The image data stored in the frame memory 36 is sent to a compression/decompression section 38 and then recorded in the memory card 16 in the card slot 14. In this way, image data representing a taken image is recorded in the memory card 16 according to a shooting operation.

The digital camera 1 of the embodiment further includes a motion sensor S1. Even when the power switch 43 is not pressed, in response to the detection of a movement by the motion sensor S1, the CPU 30 determines that the digital camera 1 is to be used and brings an analog switch SW1 into the connected state so that the power is supplied from the battery BT to each element through the analog switch SW1. In this embodiment, even when the analog switch SW1 is not in the connected state, the power is continuously supplied to the CPU 30 (the power is also supplied to the motion sensor S1 through the CPU 30) so that the CPU 30 can respond to the detection by the motion sensor S1 anytime. Therefore, for example, when the digital camera 1 is lifted by a user, the motion sensor S1 detects the movement caused by the lifting. In response to the detection by the motion sensor S1, the CPU 30 brings the analog switch SW1 into the connected state so that the power can be supplied from the battery BT to each element.

This configuration makes it possible to appropriately control the on-off state of the power according to a physical movement that occurs when the digital camera 1 is lifted, rested, or the like.

Now, there will be described processing for shooting a self-portrait with the digital camera 1 of the embodiment.

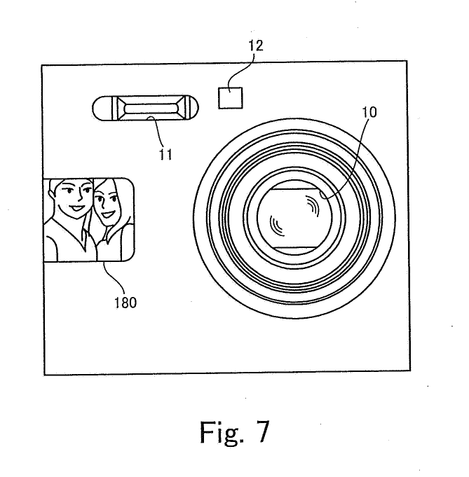

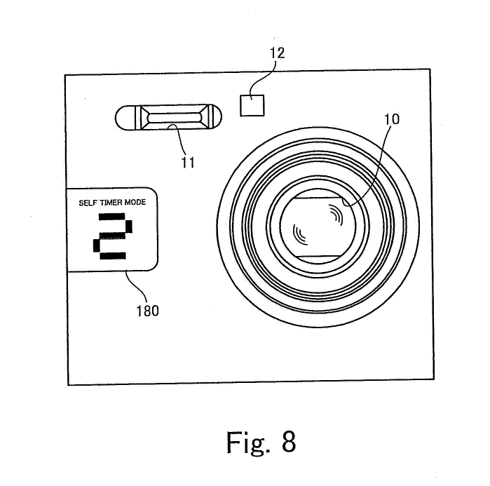

FIG. 7 is a diagram showing an image displayed on the display screen 180 when a user takes a self-portrait. FIG. 8 is a diagram showing a timer value that indicates timing for shooting a self-portrait.

As described above, the signal processing section 34 includes the AF detector capable of detecting a subject distance. When the AF detector detects a subject being in a predetermined subject-distance range, the CPU 30 that corresponds to the “display control section” of the invention determines that shooting of a self-portrait is going to take place and displays a through image on the display screen 130 on the back as well as the display screen 180 on the front. FIG. 7 shows an example in which an image of two persons is taken in a self-portrait shooting. The AF detector of the signal processing section 34 corresponds to the “distance measuring section” according to the invention.

In addition, the digital camera 1 is configured to allow a user to set the timer for shooting a self-portrait. If the timer is set, a countdown is displayed in digital form while the timer is running after the release button 41 is pressed down as shown in FIG. 8.

As described above, the invention realizes a digital camera whose exterior design has been improved further than conventional devices.

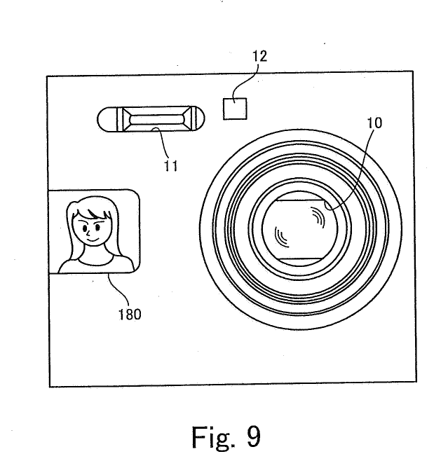

FIG. 9 is a diagram showing an example in which a self-portrait as a user-customized image is displayed.

When the image is displayed as illustrated in FIG. 9, it is possible for a user to express to others that the digital camera belongs to the user. In other words, the user can have the digital camera with a unique personal design, which is the only one in the world.

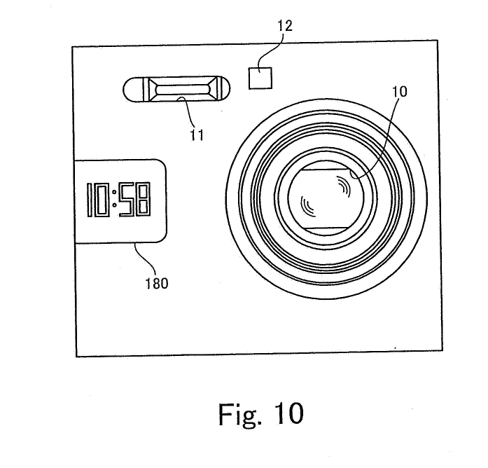

FIG. 10 is a diagram showing an example in which a clock is displayed.

As shown in FIG. 10, a clock may be displayed similarly to a typical portable telephone.

Further, although the display screen 180 of the digital camera 1 shown in FIG. 1 is relatively small, the shape of the display screen 180 is not limited thereto.

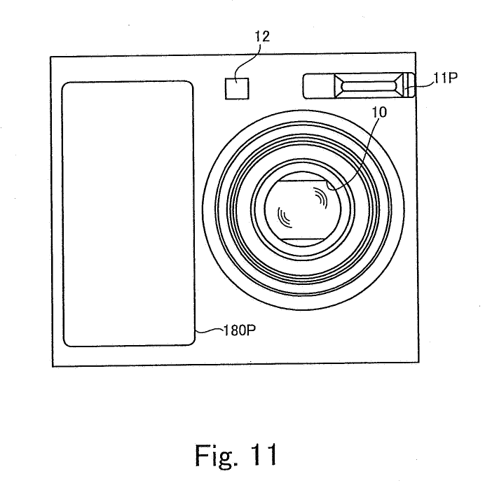

FIGS. 11 through 13 show other examples of the display screen serving as a part of the exterior design.

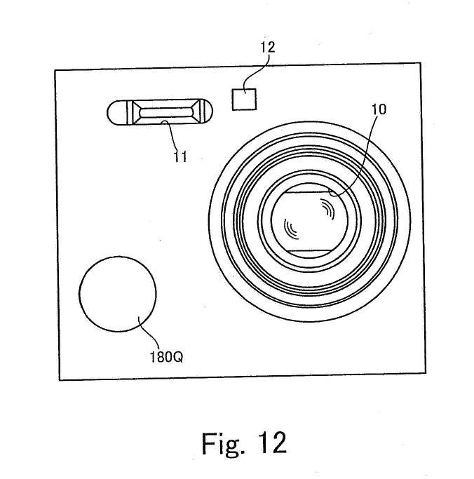

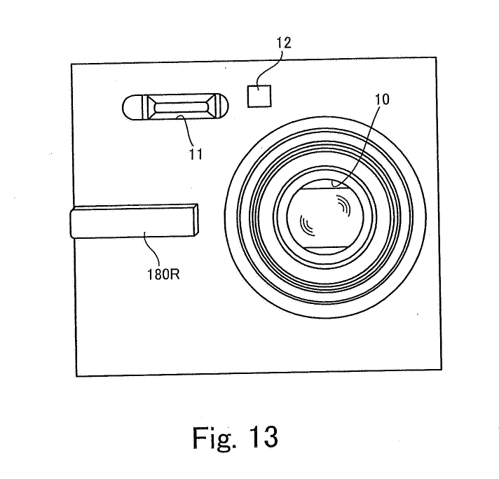

FIG. 11 shows a display screen 180P larger than the display screen 180 in FIG. 1, FIG. 12 shows a round display screen 180Q, and FIG. 13 shows a display screen 180R projecting from the camera body.

According to the invention, it is possible to provide the digital camera with an attractive exterior design by changing not only the contents displayed in the display screen but also the shape of the display screen as shown FIGS. 11 through 13.

What is claimed is:

1. A digital camera which includes an image-taking optical system and an imaging device and generates image signals by forming a subject image on the imaging device with the image-taking optical system, comprising:
a display screen which is disposed on a front surface of the digital camera and displays an image, the front surface facing a subject when the image-taking optical system is directed to the subject; and
a display control section which displays an image on the display screen.

2. A digital camera according to claim 1, wherein the display screen is disposed on the left of the image-taking optical system on the front surface when viewed from the subject.

3. A digital camera according to claim 1, wherein the display screen is adapted to continuously display an image even after a power supply is stopped.

4. A digital camera according to claim 1, wherein the display control section causes the display screen to continuously display an image for a predetermined time even after power is turned off.

5. A digital camera according to claim 1, further comprising a sensor which detects a physical movement of the digital camera caused by an external force,
wherein the display control section causes the display screen to display an image in response to a physical movement being detected by the sensor even when power is turned off.

6. A digital camera according to claim 1, further comprising a distance measuring section which measures a subject distance before shooting,
wherein the display control section causes the display screen to display an image captured by the image-taking optical system when a distance shorter than a predetermined distance is measured by the distance measuring section.
